(19) United States
(12) Patent Application Publication
(10) Pub. No.: US 2026/0223564 A1
(43) Pub. Date: Jul. 30, 2026

(54) DISPLAY PANEL AND DISPLAY APPARATUS

(71) Applicant: Wuhan Tianma Microelectronics Co., Ltd., Wuhan (CN)

(72) Inventors: Enxia Wang, Wuhan (CN); Yangzhao Ma, Wuhan (CN); Qin Yue, Wuhan (CN); Shengxiong Chen, Wuhan (CN); Wei Huang, Wuhan (CN); You Gao, Wuhan (CN)

(73) Assignee: Wuhan Tianma Microelectronics Co., Ltd., Wuhan (CN)

(21) Appl. No.: 19/629,585

(22) Filed: Mar. 26, 2026

(30) Foreign Application Priority Data
Nov. 14, 2025 (CN) 202511677539.5

(51) Int. Cl. H10K 59/35

(52) U.S. Cl. CPC H10K 59/353

(57) ABSTRACT

Provided are a display panel and a display apparatus. A pixel unit included therein comprises a first color sub-pixel, a second color sub-pixel, and a third color sub-pixel each having a non-linear edge shape. In a same pixel unit, the first and second color sub-pixels are arranged along a first direction, the third color sub-pixel and a region between the first and second color sub-pixels are arranged along a second direction, and the third color sub-pixel does not overlap with at least one of the first and second color sub-pixels in the second direction. In the pixel unit, there is no parallel region extending along the first direction between the third color sub-pixel and at least one of the first and second color sub-pixels. The edges of the shapes of the sub-pixels of the three colors can alleviate the diffraction problem.

### CROSS-REFERENCE TO RELATED APPLICATION

The present application claims priority to Chinese Patent Application No. 202511677539.5, filed on November 14, 2025, the content of which is incorporated herein by reference in its entirety.

### TECHNICAL FIELD

The present disclosure relates to the field of display technologies, and in particular, to a display panel and a display apparatus.

### BACKGROUND

With the development of display technologies, consumers have increasingly high requirements for display effects. Resolution, contrast, color, and the like are conventional parameters for evaluating display effects, and the arrangement of sub-pixels in a display apparatus directly affects these parameters. Taking an organic light-emitting display panel as an example, the closer the arrangement of the sub-pixels in the display panel, the higher the resolution of the display panel. When the arrangement of the sub-pixels in the display panel is closer, it is necessary to arrange a light-shielding structure to avoid light crosstalk between the sub-pixels, thereby improving the contrast. However, when the arrangement of the sub-pixels is closer and the light-shielding structure is arranged between the sub-pixels, the display panel has a higher probability of suffering from the diffraction problem, thereby deteriorating the color expression of the display panel.

In view of this, embodiments of the present disclosure provide a display panel and a display apparatus to address the above problem.

In a first aspect, the present disclosure provides a display panel, including a plurality of pixel units, where a pixel unit of the plurality of pixel units includes a first color sub-pixel, a second color sub-pixel, and a third color sub-pixel, and edge shapes of the first color sub-pixel, the second color sub-pixel, and the third color sub-pixel are all non-linear shapes; and where in a same pixel unit, the first color sub-pixel and the second color sub-pixel are arranged along a first direction, the third color sub-pixel and a region between the first color sub-pixel and the second color sub-pixel are arranged along a second direction, and the third color sub-pixel does not overlap with at least one of the first color sub-pixel and the second color sub-pixel in the second direction.

In a second aspect, the present disclosure provides a display apparatus, including the display panel according to the first aspect.

In the pixel unit included in the display panel according to the embodiment of the present disclosure, there is no parallel region extending along the first direction between the third color sub-pixel and at least one of the first color sub-pixel and the second color sub-pixel, thereby alleviating the diffraction problem easily caused by the narrow width of the regions between the third color sub-pixel and the first color sub-pixel as well as the second color sub-pixel. Moreover, the edges of the shapes of the first color sub-pixel, the second color sub-pixel, and the third color sub-pixel are non-linear structures, which can further reduce the possibility that the third color sub-pixel is parallel to the first color sub-pixel and the second color sub-pixel.

### BRIEF DESCRIPTION OF DRAWINGS

To illustrate the embodiments of the present disclosure more clearly, the drawings required to be used in the embodiments will be briefly introduced below. Apparently, the drawings in the description below are merely some embodiments of the present disclosure, and those of skill in the art can obtain other drawings based on these drawings without creative efforts.

FIG. 1 is a schematic diagram of a display panel according to an embodiment of the present disclosure.

FIG. 2 is a schematic diagram of a pixel unit related to an embodiment of the present disclosure.

FIG. 3 is a schematic diagram of a pixel unit in a display panel according to an embodiment of the present disclosure.

FIG. 4 is a schematic cross-sectional view taken along a direction S1-S2 in FIG. 3.

FIG. 5 is a schematic diagram of a pixel unit in a display panel according to an embodiment of the present disclosure.

FIG. 6 is a schematic cross-sectional view taken along a direction S1-S2 in FIG. 5.

FIG. 7 is a schematic diagram of a pixel unit in a display panel according to an embodiment of the present disclosure.

FIG. 8 is a schematic diagram of a pixel unit in a display panel according to an embodiment of the present disclosure.

FIG. 9 is a schematic diagram of a pixel unit in a display panel according to an embodiment of the present disclosure.

FIG. 10 is a schematic diagram of a pixel unit in a display panel according to an embodiment of the present disclosure.

FIG. 11 is a schematic diagram of a pixel unit in a display panel according to an embodiment of the present disclosure.

FIG. 12 is a schematic diagram of a pixel unit in a display panel according to an embodiment of the present disclosure.

FIG. 13 is a schematic diagram of a pixel unit in a display panel according to an embodiment of the present disclosure.

FIG. 14 is a schematic diagram of a pixel unit in a display panel according to an embodiment of the present disclosure.

FIG. 15 is a schematic diagram of a pixel unit in a display panel according to an embodiment of the present disclosure.

FIG. 16 is a schematic diagram of a pixel unit in a display panel according to an embodiment of the present disclosure.

FIG. 17 is a schematic diagram of a pixel unit in a display panel according to an embodiment of the present disclosure.

FIG. 18 is a schematic diagram of a pixel unit in a display panel according to an embodiment of the present disclosure.

FIG. 19 is a schematic diagram of a pixel unit in a display panel according to an embodiment of the present disclosure.

FIG. 20 is a schematic diagram of a pixel unit in a display panel according to an embodiment of the present disclosure.

FIG. 21 is a schematic diagram of a pixel unit in a display panel according to an embodiment of the present disclosure.

FIG. 22 is a schematic diagram of a pixel unit in a display panel according to an embodiment of the present disclosure.

FIG. 23 is a schematic diagram of a display apparatus according to an embodiment of the present disclosure.

### DESCRIPTION OF EMBODIMENTS

In order to better understand the embodiments of the present disclosure, embodiments of the present disclosure are described in detail below with reference to the accompanying drawings.

It should be clarified that the described embodiments are merely some embodiments, but not all, of the present disclosure. All other embodiments obtained by those of ordinary skill in the art without creative efforts based on the embodiments of the present disclosure shall fall within the scope of protection of the present disclosure.

Terms used in the embodiments of the present disclosure are merely for the purpose of describing particular embodiments and are not intended to limit the present disclosure. As used in the embodiments of the present disclosure and the appended claims, the singular forms “a/an” and “the” are intended to include the plural forms as well, unless the context clearly indicates otherwise.

It should be understood that the term “and/or” as used herein is merely an associative relationship describing associated objects, indicating that three relationships may exist; for example, A and/or B may mean: A exists alone, both A and B exist, and B exists alone. In addition, the character “/” as used herein generally indicates that the relationship between the objects before and after “/” is an “or” relationship.

In the description of this specification, it should be understood that the terms such as “substantially”, “approximately”, “approximate”, “about”, “roughly”, and “generally” recited in the claims and embodiments of the present disclosure mean a generally acceptable value within a reasonable process operation range or tolerance range, rather than an exact value.

It should be understood that although the terms “first”, “second” and the like may be used to describe openings and the like in the embodiments of the present disclosure, these should not be limited to these terms. These terms are used only to distinguish openings and the like from one another. For example, without departing from the scope of the embodiments of the present disclosure, a first opening may also be referred to as a second opening, and similarly, a second opening may also be referred to as a first opening. The applicant of the present disclosure, through careful and in-depth research, provides a solution to the problems existing in the prior art.

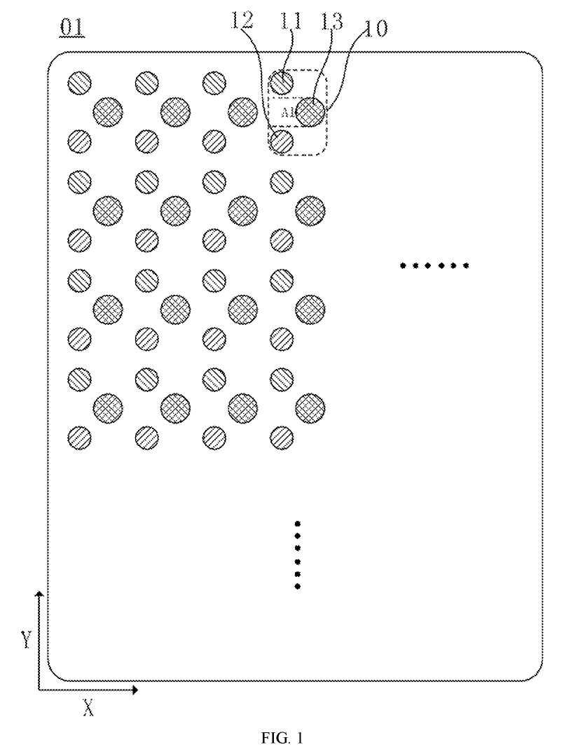

FIG. 1 is a schematic diagram of a display panel according to an embodiment of the present disclosure. In some embodiments, such as the exemplary embodiment shown in FIG. 1, the display panel 01 includes a plurality of pixel units 10. A pixel unit 10 of the plurality of pixel units 10 includes a first color sub-pixel 11, a second color sub-pixel 12, and a third color sub-pixel 13. Among the first color sub-pixel 11, the second color sub-pixel 12, and the third color sub-pixel 13, one may be a red sub-pixel, one may be a green sub-pixel, and one may be a blue sub-pixel. For example, the first color sub-pixel 11 may be a red sub-pixel, the second color sub-pixel 12 may be a green sub-pixel, and the third color sub-pixel 13 may be a blue sub-pixel. Alternatively, the first color sub-pixel 11 may be a red sub-pixel, the second color sub-pixel 12 may be a blue sub-pixel, and the third color sub-pixel 13 may be a green sub-pixel.

In some embodiments, the display panel 01 is an organic light-emitting display panel 01, each sub-pixel is an organic light-emitting diode, and a position of the sub-pixel may be defined by an opening filled with an organic light-emitting material in a pixel defining layer. The display panel 01 may also be a liquid crystal display panel 01, and a position of the sub-pixel may be defined by an opening filled with a color resist in a black matrix or by a pixel electrode. The display panel 01 according to the embodiment of the present disclosure may also be a Micro-LED display panel 01, and a position of the sub-pixel may be defined by a position where a Micro-LED is located. The display panel 01 according to the embodiment of the present disclosure may also be a display panel 01 in other forms.

In some embodiments, in a same pixel unit 10, the first color sub-pixel 11 and the second color sub-pixel 12 are arranged along a first direction Y, and the third color sub-pixel 13 and a region between the first color sub-pixel 11 and the second color sub-pixel 12 are arranged along a second direction X. Therefore, the first color sub-pixel 11 and the second color sub-pixel 12 in the same pixel unit 10 overlap with each other in the first direction Y, and the third color sub-pixel 13 overlaps with the region between the first color sub-pixel 11 and the second color sub-pixel 12 in the same pixel unit 10 in the second direction X. Moreover, among the first color sub-pixel 11, the second color sub-pixel 12 and the third color sub-pixel 13 included in the same pixel unit 10, the third color sub-pixel 13 does not overlap with at least one of the first color sub-pixel 11 and the second color sub-pixel 12 in the second direction X. The first direction Y and the second direction X intersect. Specifically, as shown in FIG. 1, the first direction Y and the second direction X may be perpendicular to each other, and the first direction Y may be a vertical direction and the second direction X may be a horizontal direction. In some embodiments, in the same pixel unit 10, the first color sub-pixel 11 and the second color sub-pixel 12 are arranged in the vertical direction; the third color sub-pixel 13 overlaps with the region between the first color sub-pixel 11 and the second color sub-pixel 12 in the horizontal direction; and the third color sub-pixel 13 does not overlap with both the first color sub-pixel 11 and the second color sub-pixel 12 in the horizontal direction.

Additionally, in some embodiments, edge shapes of the first color sub-pixel 11, the second color sub-pixel 12, and the third color sub-pixel 13 in the display panel 01 according to the embodiment of the present disclosure are all non-linear shapes, which reduces the possibility that adjacent edges of the sub-pixels of different colors in the same pixel unit 10 are parallel. That is, it reduces the possibility of parallel lengths of the adjacent edges of the sub-pixels of different colors, which in turn enables regions where distances between the sub-pixels of different colors are too small to be reduced. It should be noted that the shape of a sub-pixel may be the shape of a projection of the sub-pixel in a direction perpendicular to a plane of the display panel 01, and the edge of the sub-pixel is the edge of the projection of the sub-pixel in the direction perpendicular to the plane of the display panel 01.

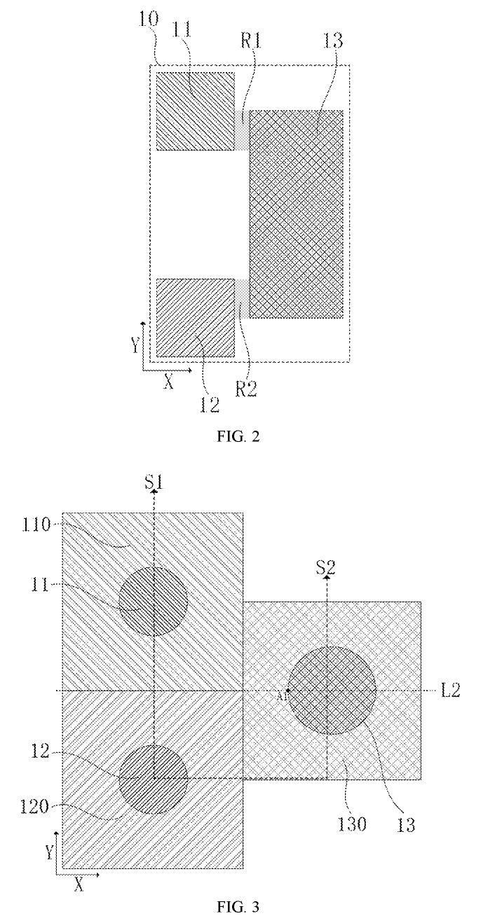

FIG. 2 is a schematic diagram of a pixel unit related to an embodiment of the present disclosure.

According to the exemplary embodiment shown in FIG. 2, in the same pixel unit 10, the third color sub-pixel 13 overlaps with the first color sub-pixel 11 and the second color sub-pixel 12 in the second direction X; and the third color sub-pixel 13, the first color sub-pixel 11, and the second color sub-pixel 12 are all rectangular structures. In some embodiments, a parallel intermediate region between the third color sub-pixel 13 and the first color sub-pixel 11 has a relatively small width in the horizontal direction and a relatively large length in the vertical direction, which is prone to diffraction phenomenon. Likewise, a parallel intermediate region between the third color sub-pixel 13 and the second color sub-pixel 12 has a relatively small width in the horizontal direction and a relatively large length in the vertical direction, which is also prone to diffraction phenomenon. In particular, when a light-shielding structure such as a black matrix or a metal wire of a mesh-shaped touch electrode is provided on a side of a region between the sub-pixels facing a light-emitting surface of the display panel 01, it is equivalent that a light-shielding structure with a relatively narrow width and a relatively large length is provided on sides of the parallel intermediate region between the third color sub-pixel 13 and the first color sub-pixel 11, as well as the parallel intermediate region between the third color sub-pixel 13 and the second color sub-pixel 12 that face the light-emitting surface of the display panel 01, thereby easily resulting in the diffraction and in turn affecting the display effect.

In some embodiments (with reference to FIG. 1), in the pixel unit 10 included in the display panel 01 according to the embodiment of the present disclosure, there is no parallel region extending along the first direction Y between the third color sub-pixel 13 and at least one of the first color sub-pixel 11 and the second color sub-pixel 12, thereby alleviating the diffraction problem easily caused by the narrow width of the regions between the third color sub-pixel 13 and the first color sub-pixel 11 as well as the second color sub-pixel 12. Moreover, the edges of the shapes of the first color sub-pixel 11, the second color sub-pixel 12, and the third color sub-pixel 13 are non-linear structures, which can further reduce the possibility that the third color sub-pixel 13 is parallel to the first color sub-pixel 11 and the second color sub-pixel 12. In addition, the edges of the shapes of the first color sub-pixel 11, the second color sub-pixel 12, and the third color sub-pixel 13 being non-linear structures can realize that, as shown in FIG. 1, the edge shape of the third color sub-pixel 13 may be such that the closer to the first color sub-pixel 11 in the first direction Y, the farther from the first color sub-pixel 11 in the second direction X. Additionally, the edge shape of the second color sub-pixel 12 may be such that the closer to the second color sub-pixel 12 in the first direction Y, the farther from the second color sub-pixel 12 in the second direction X. That is, the distance between the third color sub-pixel 13 and the first color sub-pixel 11 and the distance between the third color sub-pixel 13 and the second color sub-pixel 12 are both increased, which in turn reduces the risk of the diffraction phenomenon.

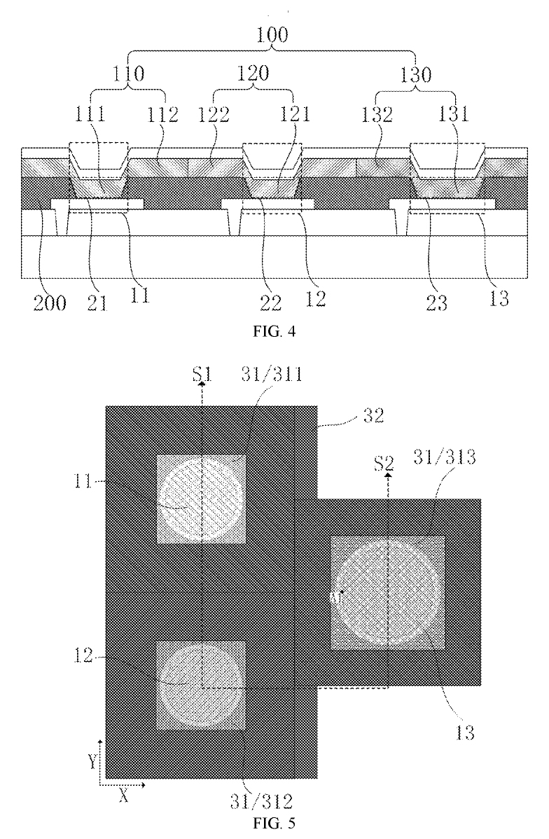

FIG. 3 is a schematic diagram of a pixel unit in a display panel according to an embodiment of the present disclosure. FIG. 4 is a schematic cross-sectional view taken along a direction S1-S2 in FIG. 3.

According to the exemplary embodiment shown in conjunction with FIGS. 3 and 4, the display panel 01 includes a light-emitting material layer 100 and a pixel defining layer 200, where the pixel defining layer 200 includes a plurality of openings therein and the light-emitting material layer 100 includes light-emitting materials, and the light-emitting materials are filled in the openings of the pixel defining layer 200. In some embodiments, a shape of an opening of the openings included in the pixel defining layer 200 defines a shape of a sub-pixel of the sub-pixels. Therefore, when the pixel unit 10 includes the first color sub-pixel 11, the second color sub-pixel 12, and the third color sub-pixel 13, the pixel defining layer 200 includes a first opening 21 defining a region where the first color sub-pixel 11 is located, a second opening 22 defining a region where the second color sub-pixel 12 is located, and a third opening 23 defining a region where the third color sub-pixel 13 is located. The light-emitting materials included in the light-emitting material layer 100 may be organic light-emitting materials, where the light-emitting material layer 100 includes light-emitting materials capable of emitting light of different colors. Therefore, when the pixel unit 10 includes the first color sub-pixel 11, the second color sub-pixel 12, and the third color sub-pixel 13, the light-emitting material layer 100 includes a first color light-emitting material 111, a second color light-emitting material 121, and a third color light-emitting material 131; and the first color light-emitting material 111 is filled in the first opening 21 of the pixel defining layer 200, the second color light-emitting material 121 is filled in the second opening 22, and the third color light-emitting material 131 is filled in the third opening 23. In some embodiments, an edge shape of the first opening 21, an edge shape of the second opening 22, and an edge shape of the third opening 23 are non-linear shapes, so that the edge shape of the first color sub-pixel 11, the edge shape of the second color sub-pixel 12, and the edge shape of the third color sub-pixel 13 are non-linear shapes. In some embodiments, as shown in FIG. 4, the edge shapes of the openings may be the shapes of the upper edges of the openings.

When preparing the organic light-emitting materials, a mask plate may be used and alignment may be performed between hollow portions of the mask plate and the openings in the pixel defining layer 200, so that the light-emitting materials can be deposited into the openings of the pixel defining layer 200 through the hollow portions of the mask plate. However, due to the limitations of alignment accuracy, deposition processes, and the like, in order to ensure that the openings of the pixel defining layer 200 are completely filled with the light-emitting materials, the areas of the hollow portions of the mask plate may be designed to be larger than the areas of the openings corresponding thereto. Therefore, in some embodiments, the light-emitting material layer 100 includes light-emitting material blocks of different colors therein, and the light-emitting material blocks include the portions filled in the openings of the pixel defining layer 200 and the portions outside the openings. When the pixel unit 10 includes the first color sub-pixel 11, the second color sub-pixel 12, and the third color sub-pixel 13 therein, the light-emitting material layer 100 includes a first color light-emitting material block 110, a second color light-emitting material block 120, and a third color light-emitting material block 130. In some embodiments, the first color sub-pixel 11 includes a portion of the first color light-emitting material block 110 located in the first opening 21 and a portion 112 located outside the first opening 21; the second color sub-pixel 12 includes a portion of the second color light-emitting material block 120 located in the second opening 22 and a portion 122 located outside the second opening 22; and the third color sub-pixel 13 includes a portion of the third color light-emitting material block 130 located in the third opening 23 and a portion 132 located outside the third opening 23.

In some embodiments, edge shapes of the first color light-emitting material block 110, the second color light-emitting material block 120, and the third color light-emitting material block 130 may all be rectangular. It can be understood that the shapes of the hollow portions in the mask plate used in depositing the light-emitting materials, which are aligned with the openings of the pixel defining layer 200, are rectangular. Therefore, when depositing the light-emitting materials included in the sub-pixels of the display panel 01, the mask plate used has a simple structure and relatively low processing requirements for preparing the mask plate, which are easy to implement.

In some embodiments, such as the exemplary embodiment shown in FIG. 3, in the first color light-emitting material block 110, the second color light-emitting material block 120, and the third color light-emitting material block 130 respectively corresponding to the first color sub-pixel 11, the second color sub-pixel 12, and the third color sub-pixel 13 in the same pixel unit 10, a second center line L2 of the third color light-emitting material block 130 is parallel to a boundary line between the first color light-emitting material block 110 and the second color light-emitting material block 120. Herein, the second center line L2 of the edge shape of the third color light-emitting material block 130 is parallel to the second direction X, and the second center line L2 passes through a midpoint of the third color light-emitting material block 130. Because the third color sub-pixel 13 overlaps with the region between the first color sub-pixel 11 and the second color sub-pixel 12 in the second direction X in the same pixel unit 10. That is, the third opening 23 overlaps with the region between the first opening 21 and the second opening 22 in the second direction X. When preparing the light-emitting materials, the second center line L2 of the third color light-emitting material block 130 coincides with the boundary line between the first color light-emitting material block 110 and the second color light-emitting material block 120, which can effectively reduce the risk that the second center line L2 of the third color light-emitting material block 130 deviates from the third opening 23 in the second direction X, thereby avoiding the color deficiency problem.

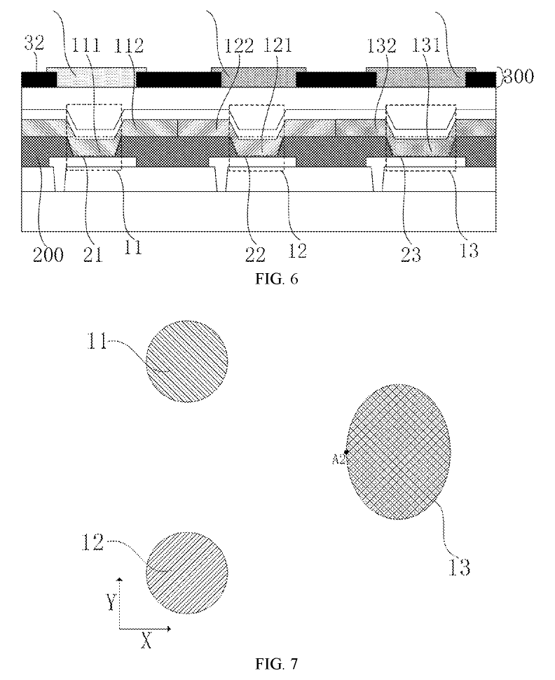

FIG. 5 is a schematic diagram of a pixel unit in a display panel according to an embodiment of the present disclosure. FIG. 6 is a schematic cross-sectional view taken along a direction S1-S2 in FIG. 5.

In some embodiments, in conjunction with FIGS. 5 and 6, the display panel 01 further includes a filter layer 300. The filter layer 300 includes color resist blocks 31, and at least one of the first opening 21, the second opening 22, and the third opening 23 overlaps with a color resist block 31 of the color resist blocks 31 in the direction Z perpendicular to the plane of the display panel 01. According to the exemplary embodiment shown in FIGS. 5 and 6, a first color resist block 311 overlaps with the first opening 21 in the direction Z perpendicular to the plane of the display panel 01, a second color resist block 312 overlaps with the second opening 22 in the direction Z perpendicular to the plane of the display panel 01, and a third color resist block 323 overlaps with the third opening 23 in the direction Z perpendicular to the plane of the display panel 01. The color resist blocks 31 may filter light to make the chromaticity of the light purer, and the color resist blocks 31 may reduce the amount of ambient light incident below the sub-pixels in the display panel to improve the display effect.

In addition, the filter layer 300 may further include a black matrix 32 besides the color resist blocks 31, the black matrix 32 may include hollow portions, and at least portions of the color resist blocks 31 may be filled in the hollow portions of the black matrix 32. In some embodiments, the arrangement and shape design of the first color sub-pixel 11, the second color sub-pixel 12, and the third color sub-pixel 13 in the pixel unit 10 can effectively alleviate the diffraction problem of light passing through the black matrix 32.

The shapes of the sub-pixels in the pixel unit 10 are described. It should be noted that, on the premise that there is no technical conflict, a new solution obtained by combining the following embodiments of the shapes of the sub-pixels in the pixel unit 10 with any one of the foregoing embodiments is also within the protection scope of the present disclosure.

The edge shape of the first color sub-pixel 11 may include a circular arc and/or an elliptical arc, and thus the shape of the first color sub-pixel 11 may be a circle, an ellipse, a "goose egg" shape, and the like. For example, as shown in FIGS. 1, 3, and 5, the shape of the first color sub-pixel 11 may be a circle.

The edge shape of the second color sub-pixel 12 may include a circular arc and/or an elliptical arc, and thus the shape of the second color sub-pixel 12 may be a circle, an ellipse, a "goose egg" shape, and the like. For example, as shown in FIGS. 1, 3, and 5, the shape of the second color sub-pixel 12 may be a circle.

The edge shape of the third color sub-pixel 13 may include a circular arc and/or an elliptical arc, and thus the shape of the third color sub-pixel 13 may be a circle, an ellipse, a "goose egg" shape, and the like.

In some embodiments, such as the exemplary embodiments shown in FIGS. 1, 3, and 5, the edge shape of the third color sub-pixel 13 is a circle, and the circular third color sub-pixel 13 is relatively easy to implement. Moreover, with continued reference to FIGS. 1, 3, and 5, in the same pixel unit 10, a point A1 in the circular third color sub-pixel 13 that is closest to the column where the first color sub-pixel 11 and the second color sub-pixel 12 are located in the second direction X may overlap with the region between the first color sub-pixel 11 and the second color sub-pixel 12 in the second direction X, so that other points in the circular third color sub-pixel 13 are further away from the first color sub-pixel 11 and the second color sub-pixel 12 than the point A1. This may effectively avoid unduly small distances between the third color sub-pixel 13 and the first color sub-pixel 11 as well as between the third color sub-pixel 13 and the second color sub-pixel 12, thereby effectively alleviating the diffraction problem.

FIG. 7 is a schematic diagram of a pixel unit in a display panel according to an embodiment of the present disclosure.

In some embodiments, such as the exemplary embodiment shown in FIG. 7, the edge shape of the third color sub-pixel 13 is an ellipse. In some embodiments, a major axis of the ellipse is parallel to the first direction Y, and a length of the third color sub-pixel 13 in the first direction Y is larger than a length of the third color sub-pixel 13 in the second direction X. Therefore, the third color sub-pixel 13 in the same pixel unit 10 may achieve better color rendering together with the first color sub-pixel 11 and the second color sub-pixel 12 and avoid an increase in a width of the pixel unit 10 in the second direction X, thereby preventing the arrangement of the pixel units 10 from being affected. Similarly, in the same pixel unit 10, a point A2 in the elliptical third color sub-pixel 13 that is closest to the column where the first color sub-pixel 11 and the second color sub-pixel 12 are located in the second direction X may overlap with the region between the first color sub-pixel 11 and the second color sub-pixel 12 in the second direction X, so that other points in the elliptical third color sub-pixel 13 are further away from the first color sub-pixel 11 and the second color sub-pixel 12 than the point A2. This may effectively avoid unduly small distances between the third color sub-pixel 13 and the first color sub-pixel 11 as well as between the third color sub-pixel 13 and the second color sub-pixel 12, thereby effectively alleviating the diffraction problem.

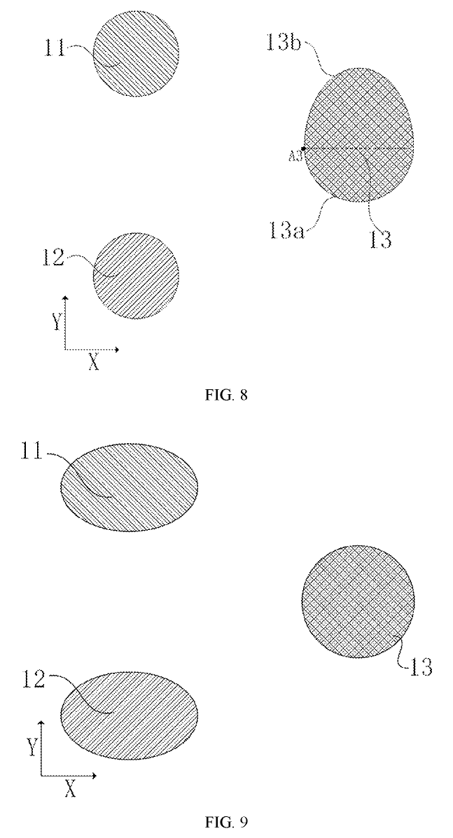

FIG. 8 is a schematic diagram of a pixel unit in a display panel according to an embodiment of the present disclosure.

In some embodiments, such as the exemplary embodiment shown in FIG. 8, the edge shape of the third color sub-pixel 13 includes a circular arc 13a and an elliptical arc 13b arranged along the first direction Y. In some embodiments, the circular arc 13a and the elliptical arc 13b are connected to form a "goose egg" shape. A major axis of an ellipse corresponding to the elliptical arc 13b is parallel to the first direction Y, and thus the "goose egg" shape formed by connecting the circular arc 13a and the elliptical arc 13b has a length direction parallel to the first direction Y and a width direction parallel to the second direction X. The third color sub-pixel 13 in the same pixel unit 10 may be configured to achieve better color rendering together with the first color sub-pixel 11 and the second color sub-pixel 12 and avoid an increase in a width of the pixel unit 10 in the second direction X, thereby preventing the arrangement of the pixel units 10 from being affected. Further, according to the brightness characteristic of the first color sub-pixel 11 and the brightness characteristic of the second color sub-pixel 12, the portion of the third color sub-pixel 13 including the circular arc 13a may be arranged close to the first color sub-pixel 11, and the portion of the third color sub-pixel 13 including the elliptical arc 13b may be arranged close to the second color sub-pixel 12; or, the portion of the third color sub-pixel 13 including the elliptical arc 13b may be arranged close to the first color sub-pixel 11, and the portion of the third color sub-pixel 13 including the circular arc 13a may be arranged close to the second color sub-pixel 12, so as to achieve better white balance.

Similarly, according to the exemplary embodiment shown in FIG. 8, in the same pixel unit 10, a point A3 in the "goose egg" third color sub-pixel 13 that is closest to the column where the first color sub-pixel 11 and the second color sub-pixel 12 are located in the second direction X may overlap with the region between the first color sub-pixel 11 and the second color sub-pixel 12 in the second direction X, so that other points in the "goose egg" third color sub-pixel 13 are further away from the first color sub-pixel 11 and the second color sub-pixel 12 than the point A3, which can effectively avoid unduly small distances between the third color sub-pixel 13 and the first color sub-pixel 11 as well as between the third color sub-pixel 13 and the second color sub-pixel 12, thereby effectively alleviating the diffraction problem.

In some embodiments, the edge shape of the first color sub-pixel 11 is a circle, and/or the edge shape of the second color sub-pixel 12 is a circle. In addition, the edge shape of the first color sub-pixel 11 and the edge shape of the second color sub-pixel 12 in the same pixel unit 10 may be the same. For example, according to the exemplary embodiments shown in FIGS. 1, 3, 5, 7, and 8, the edge shapes of the first color sub-pixel 11 and the second color sub-pixel 12 are all circles. The edge shape of the first color sub-pixel 11 and the edge shape of the second color sub-pixel 12 in the same pixel unit 10 may also be different, for example, one is a circle and the other is another shape.

In some embodiments, the edge shape of the third color sub-pixel 13 in the same pixel unit 10 may be a circle, an ellipse, or a "goose egg" shape formed by connecting the circular arc 13a and the elliptical arc 13b. For example, according to the exemplary embodiments shown in FIGS. 1, 3, and 5, the edge shape of the first color sub-pixel 11 is a circle, the edge shape of the second color sub-pixel 12 is a circle, and the edge shape of the third color sub-pixel 13 is a circle. For example, according to the exemplary embodiment shown in FIG. 7, the edge shape of the first color sub-pixel 11 is a circle, the edge shape of the second color sub-pixel 12 is a circle, and the edge shape of the third color sub-pixel 13 is an ellipse. For example, according to the exemplary embodiment shown in FIG. 8, the edge shape of the first color sub-pixel 11 is a circle, the edge shape of the second color sub-pixel 12 is a circle, and the edge shape of the third color sub-pixel 13 is a "goose egg" shape formed by connecting the circular arc 13a and the elliptical arc 13b.

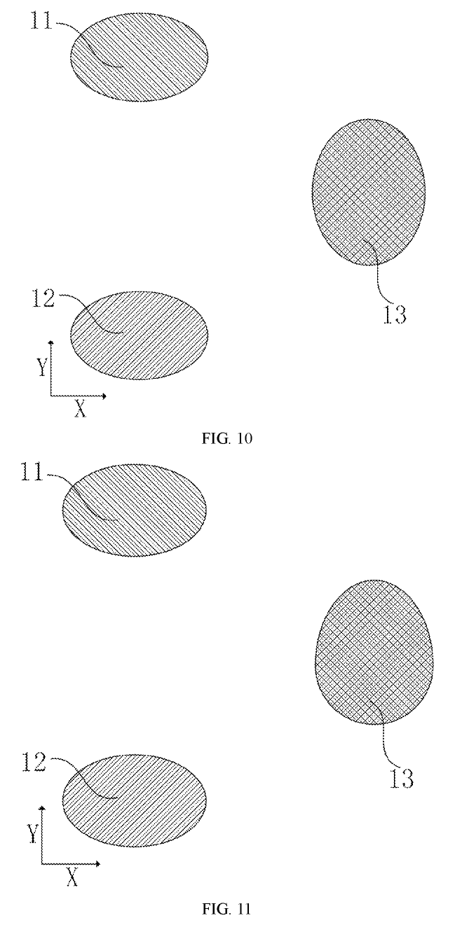

FIG. 9 is a schematic diagram of a pixel unit in a display panel according to an embodiment of the present disclosure. FIG. 10 is a schematic diagram of a pixel unit in a display panel according to an embodiment of the present disclosure. FIG. 11 is a schematic diagram of a pixel unit in a display panel according to an embodiment of the present disclosure.

In some embodiments, such as the exemplary embodiments shown in FIGS. 9 to 11, the edge shape of the first color sub-pixel 11 is an ellipse, and a major axis of the ellipse is parallel to the second direction X, and/or the edge shape of the second color sub-pixel 12 is an ellipse, and a major axis of the ellipse is parallel to the second direction X. Because the first color sub-pixel 11 and the second color sub-pixel 12 in the same pixel unit 10 are arranged along the first direction Y, if the major axis of the elliptical one of the first color sub-pixel 11 and the second color sub-pixel 12 is parallel to the first direction Y, the width occupied by the pixel unit 10 in the first direction Y will be relatively large, which is not conducive to the color rendering of different color sub-pixels in the pixel unit 10. In some embodiments, when the edge shape of at least one of the first color sub-pixel 11 and the second color sub-pixel 12 is an ellipse, the arrangement thereof is reasonably designed, which is beneficial to ensuring the color rendering effect of the sub-pixels of different colors in the pixel unit 10, and the area occupied by the pixel unit 10 is relatively reasonable in both the first direction Y and the second direction X. In addition, the edge shape of the first color sub-pixel 11 and the edge shape of the second color sub-pixel 12 in the same pixel unit 10 may be the same. For example, according to the embodiments shown in FIGS. 9 to 11, the edge shapes of the first color sub-pixel 11 and the second color sub-pixel 12 are both ellipses. The edge shape of the first color sub-pixel 11 and the edge shape of the second color sub-pixel 12 in the same pixel unit 10 may also be different, for example, one is an ellipse and the other is another shape.

In some embodiments, the edge shape of the third color sub-pixel 13 in the same pixel unit 10 may be a circle, an ellipse, or a "goose egg" shape formed by connecting the circular arc 13a and the elliptical arc 13b. For example, according to the exemplary embodiment shown in FIG. 9, the edge shape of the first color sub-pixel 11 is an ellipse, the edge shape of the second color sub-pixel 12 is an ellipse, and the edge shape of the third color sub-pixel 13 is a circle. For example, according to the exemplary embodiment shown in FIG. 10, the edge shape of the first color sub-pixel 11 is an ellipse, the edge shape of the second color sub-pixel 12 is an ellipse, and the edge shape of the third color sub-pixel 13 is an ellipse. For example, according to the exemplary embodiment shown in FIG. 11, the edge shape of the first color sub-pixel 11 is an ellipse, the edge shape of the second color sub-pixel 12 is an ellipse, and the edge shape of the third color sub-pixel 13 is a "goose egg" shape formed by connecting the circular arc 13a and the elliptical arc 13b.

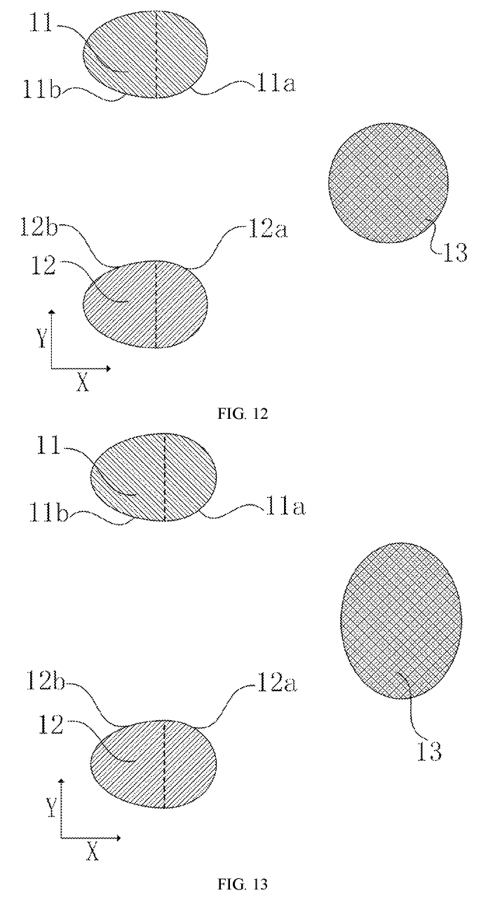

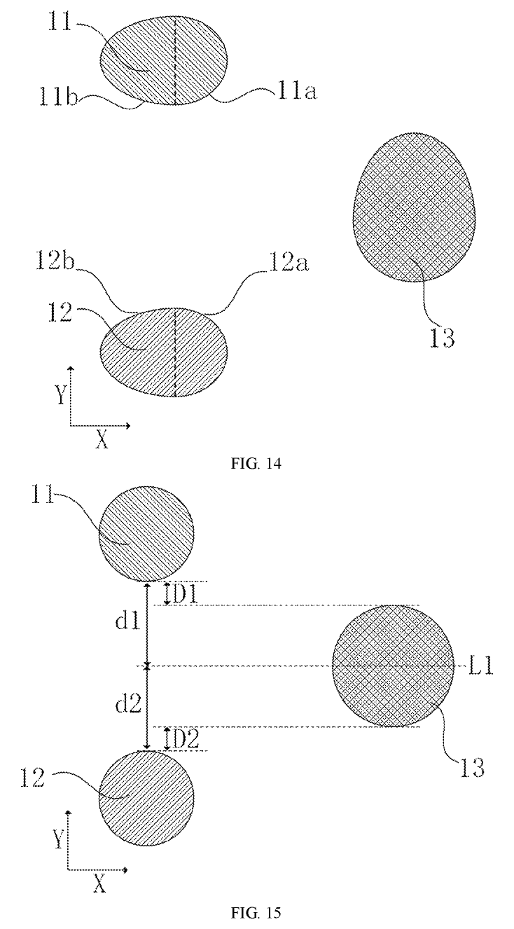

FIG. 12 is a schematic diagram of a pixel unit in a display panel according to an embodiment of the present disclosure. FIG. 13 is a schematic diagram of a pixel unit in a display panel according to an embodiment of the present disclosure. FIG. 14 is a schematic diagram of a pixel unit in a display panel according to an embodiment of the present disclosure.

In some embodiments, such as the embodiments shown in FIGS. 12 to 14, the edge shape of the first color sub-pixel 11 includes a circular arc 11a and an elliptical arc 11b that are arranged along the second direction X, and/or the edge shape of the second color sub-pixel 12 includes a circular arc 12a and an elliptical arc 12b that are arranged along the second direction X. A major axis of an ellipse corresponding to the elliptical arc 12b is parallel to the second direction X. Because the first color sub-pixel 11 and the second color sub-pixel 12 in the same pixel unit 10 are arranged along the first direction Y, if the major axis of the "goose egg" sub-pixel of the first color sub-pixel 11 and the second color sub-pixel 12 in the same pixel unit 10 is parallel to the first direction Y, the width occupied by the pixel unit 10 in the first direction Y is relatively large, which is not conducive to the color rendering of different color sub-pixels in the pixel unit 10. In some embodiments, when the edge shape of at least one of the first color sub-pixel 11 and the second color sub-pixel 12 is a "goose egg" shape, the arrangement thereof is reasonably designed, which is beneficial to ensuring the color rendering effect of the sub-pixels of different colors in the pixel unit 10, and the area occupied by the pixel unit 10 is relatively reasonable in both the first direction Y and the second direction X. In addition, the edge shape of the first color sub-pixel 11 and the edge shape of the second color sub-pixel 12 in the same pixel unit 10 may be the same. For example, according to the exemplary embodiments shown in FIGS. 12 to 14, the edge shapes of the first color sub-pixel 11 and the second color sub-pixel 12 all include a circular arc and an elliptical arc that are connected. The edge shape of the first color sub-pixel 11 and the edge shape of the second color sub-pixel 12 in the same pixel unit 10 may also be different, for example, one is a "goose egg" shape including a circular arc and an elliptical arc and the other is another shape.

In some embodiments, the edge shape of the third color sub-pixel 13 in the same pixel unit 10 may be a circle, an ellipse, or a "goose egg" shape formed by connecting the circular arc 13a and the elliptical arc 13b. For example, according to the exemplary embodiment shown in FIG. 12, the edge shape of the first color sub-pixel 11 is a "goose egg" shape formed by connecting the circular arc 11a and the elliptical arc 11b, the edge shape of the second color sub-pixel 12 is a "goose egg" shape formed by connecting the circular arc 12a and the elliptical arc 12b, and the edge shape of the third color sub-pixel 13 is a circle. For example, according to the exemplary embodiment shown in FIG. 13, the edge shape of the first color sub-pixel 11 is a "goose egg" shape formed by connecting the circular arc 11a and the elliptical arc 11b, the edge shape of the second color sub-pixel 12 is a "goose egg" shape formed by connecting the circular arc 12a and the elliptical arc 12b, and the edge shape of the third color sub-pixel 13 is an ellipse. For example, according to the exemplary embodiment shown in FIG. 14, the edge shape of the first color sub-pixel 11 is a "goose egg" shape formed by connecting the circular arc 11a and the elliptical arc 11b, the edge shape of the second color sub-pixel 12 is a "goose egg" shape formed by connecting the circular arc 12a and the elliptical arc 12b, and the edge shape of the third color sub-pixel 13 is a "goose egg" shape formed by connecting the circular arc 13a and the elliptical arc 13b.

Additionally, according to the exemplary embodiments shown in FIGS. 12 to 14, when the edge shape of at least one of the first color sub-pixel 11 and the second color sub-pixel 12 is a "goose egg" shape including a circular arc and an elliptical arc arranged along the second direction X, the portion including the circular arc is located on a side of the elliptical arc facing the third color sub-pixel 13 in the same pixel unit 10 in the second direction X, so as to achieve a better rendering effect with the third color sub-pixel 13, and to reduce the risk of cross color with sub-pixels in other pixel units 10.

The arrangement of the sub-pixels in the pixel unit 10 is described. It should be noted that, on the premise that there is no technical conflict, a new solution obtained by combining the following embodiments of the arrangement of the sub-pixels in the pixel unit 10 with any one of the foregoing embodiments is also within the protection scope of the present disclosure. For example, unless otherwise specified, the following embodiments are described by taking that the edge shapes of the first color sub-pixel 11, the second color sub-pixel 12, and the third color sub-pixel 13 are all circles as an example, but these embodiments are also applicable to the situations where the first color sub-pixel 11, the second color sub-pixel 12, and the third color sub-pixel 13 are ellipses, "goose egg" shapes and the like.

FIG. 15 is a schematic diagram of a pixel unit in a display panel according to an embodiment of the present disclosure.

In some embodiments, in the same pixel unit 10, the third color sub-pixel 13 does not overlap with both the first color sub-pixel 11 and the second color sub-pixel 12 in the second direction X. That is, according to the exemplary embodiment shown in FIG. 15, a distance between the third color sub-pixel 13 and the first color sub-pixel 11 in the first direction Y is D1, and a distance between the third color sub-pixel 13 and the second color sub-pixel 12 in the first direction Y is D2, where D1 > 0 and D2 > 0. When the third color sub-pixel 13 does not overlap with the first color sub-pixel 11 and the second color sub-pixel 12 in the same pixel unit 10 in the second direction X, there is no parallel region extending along the first direction Y between the third color sub-pixel 13 and the first color sub-pixel 11, and there is no parallel region extending along the first direction Y between the third color sub-pixel 13 and the second color sub-pixel 12, which ensures relatively large distances between the third color sub-pixel 13 and the first color sub-pixel 11 as well as between the third color sub-pixel 13 and the second color sub-pixel 12, thereby effectively alleviating the diffraction problem.

In some embodiments, such as the exemplary embodiment shown in FIG. 15, D1 = D2. That is, in the same pixel unit 10, the distance between the third color sub-pixel 13 and the first color sub-pixel 11 in the first direction Y is substantially equal to the distance between the third color sub-pixel 13 and the second color sub-pixel 12 in the first direction Y. Considering the influence of unavoidable factors such as process errors, D1 and D2 are equal within an error range, and D1 is approximately equal to D2 in an actual display panel 01. In this embodiment, D1=D2 can enable the third color sub-pixel 13 to achieve good color rendering with both the first color sub-pixel 11 and the second color sub-pixel 12.

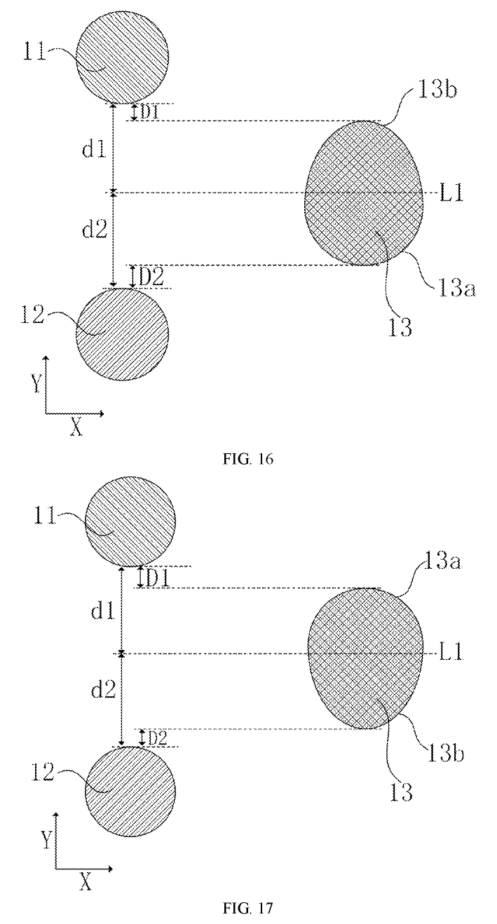

FIG. 16 is a schematic diagram of a pixel unit in a display panel according to an embodiment of the present disclosure. FIG. 17 is a schematic diagram of a pixel unit in a display panel according to an embodiment of the present disclosure.

In an embodiment, as shown in FIGS. 16 and 17, D1 < D2 or D1 > D2. That is, in the same pixel unit 10, the distance between the third color sub-pixel 13 and the first color sub-pixel 11 in the first direction Y is designed to be unequal to the distance between the third color sub-pixel 13 and the second color sub-pixel 12 in the first direction Y. In some embodiments, a difference between D1 and D2 may be 4μm to 5μm. In some embodiments, the distance between the third color sub-pixel 13 and the first color sub-pixel 11 and the distance between the third color sub-pixel 13 and the second color sub-pixel 12 in the first direction Y may be set according to the brightness characteristic of the first color sub-pixel 11, the brightness characteristics of the second color sub-pixel 12 and the third color sub-pixel 13 and the like, so as to ensure that the third color sub-pixel 13 can achieve reasonable color rendering with the first color sub-pixel 11 and the second color sub-pixel 12 to obtain better white balance.

For example, according to the exemplary embodiment shown in FIG. 16, the third color sub-pixel 13 includes a circular arc 13a and an elliptical arc 13b, and the elliptical arc 13b is located on a side of the circular arc 13a facing the first color sub-pixel 11 in the first direction Y, so that in the same pixel unit 10, a distance D1 between the third color sub-pixel 13 and the first color sub-pixel 11 in the first direction Y is smaller than a distance D2 between the third color sub-pixel 13 and the second color sub-pixel 12 in the first direction Y. In some embodiments, the distance between the portion of the third color sub-pixel 13 corresponding to the elliptical arc 13b and the first color sub-pixel 11 in the second direction X is larger than the distance between the portion of the third color sub-pixel 13 corresponding to the circular arc 13a and the second color sub-pixel 12 in the second direction X. By setting the third color sub-pixel 13 to be closer to the first color sub-pixel 11 in the first direction Y, the third color sub-pixel 13 can be enabled to achieve effective color rendering with the first color sub-pixel 11, thereby being conducive to realizing white balance.

For example, according to the exemplary embodiment shown in FIG. 17, the third color sub-pixel 13 includes a circular arc 13a and an elliptical arc 13b, and the elliptical arc 13b is located on a side of the circular arc 13a facing the second color sub-pixel 12 in the first direction Y, so that in the same pixel unit 10, a distance D2 between the third color sub-pixel 13 and the second color sub-pixel 12 in the first direction Y is smaller than a distance D1 between the third color sub-pixel 13 and the first color sub-pixel 11 in the first direction Y. In the embodiment of the present disclosure, the distance between the portion of the third color sub-pixel 13 corresponding to the elliptical arc 13b and the second color sub-pixel 12 in the second direction X is larger than the distance between the portion of the third color sub-pixel 13 corresponding to the circular arc 13a and the first color sub-pixel 11 in the second direction X. By setting the third color sub-pixel 13 to be closer to the second color sub-pixel 12 in the first direction Y, the third color sub-pixel 13 can be enabled to achieve effective color rendering with the second color sub-pixel 12, thereby being conducive to realizing white balance.

In some embodiments, such as the exemplary embodiments shown in FIGS. 15 to 17, a first center line L1 of the edge shape of the third color sub-pixel 13 is parallel to the second direction X. It should be noted that the first center line L1 is a virtual straight line and the virtual straight line passes through the first color sub-pixel 11. In the same pixel unit 10, a distance between the first center line of the third color sub-pixel 13 and the first color sub-pixel 11 in the first direction Y is d1, and a distance between the first center line of the third color sub-pixel 13 and the second color sub-pixel 12 in the first direction Y is d2, where d1 = d2. That is, in the same pixel unit 10, a distance between a center point of the third color sub-pixel 13 and the first color sub-pixel 11 in the first direction Y is equal to a distance between a center point of the third color sub-pixel 13 and the second color sub-pixel 12 in the first direction Y. Considering the influence of unavoidable factors such as process errors, d1 and d2 are equal within an error range, and d1 is approximately equal to d2 in an actual display panel 01.

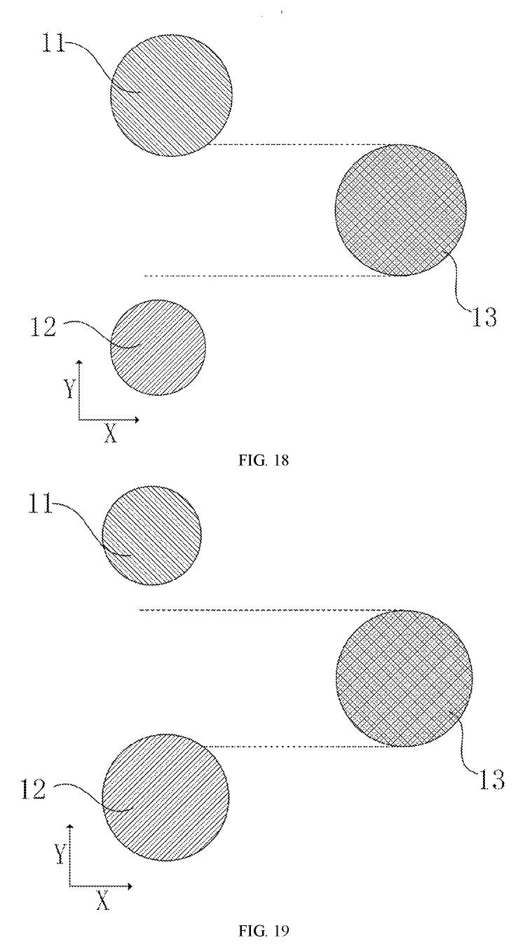

FIG. 18 is a schematic diagram of a pixel unit in a display panel according to an embodiment of the present disclosure. FIG. 19 is a schematic diagram of a pixel unit in a display panel according to an embodiment of the present disclosure.

In some embodiments, such as the exemplary embodiments shown in FIGS. 18 and 19, in the same pixel unit 10, the third color sub-pixel 13 overlaps with one of the first color sub-pixel 11 and the second color sub-pixel 12 in the second direction X and does not overlap with the other one in the second direction X. In some embodiments, the sub-pixel overlapping with the third color sub-pixel 13 in the second direction X can better achieve color rendering with the third color sub-pixel 13 in the pixel unit 10. For example, according to the exemplary embodiment shown in FIG. 18, in the same pixel unit 10, the third color sub-pixel 13 partially overlaps with the first color sub-pixel 11 in the second direction X and does not overlap with the second color sub-pixel 12 in the second direction X. For example, according to the exemplary embodiment shown in FIG. 19, in the same pixel unit 10, the third color sub-pixel 13 partially overlaps with the second color sub-pixel 12 in the second direction X and does not overlap with the first color sub-pixel 11 in the second direction X.

In some embodiments, in the same pixel unit 10, an area of the sub-pixel overlapping with the third color sub-pixel 13 in the second direction X is larger than an area of the sub-pixel not overlapping with the third color sub-pixel 13 in the second direction X. Therefore, when the area of one of the first color sub-pixel 11and the second color sub-pixel 12 is designed to be larger and the area of the other one of the first color sub-pixel 11 and the second color sub-pixel 12 is designed to be smaller in consideration of at least one factor such as white balance, brightness, and light-emitting efficiency, and when the larger one of the first color sub-pixel 11 and the second color sub-pixel 12 overlaps with the third color sub-pixel 13 in the second direction X, a distance between the larger one of the first color sub-pixel 11 and the smaller one of the first color sub-pixel 11 and the second color sub-pixel 12 in the second direction X is relatively small, which can prevent a width of the pixel unit 10 in the first direction Y from being too large when the first color sub-pixel 11 and the second color sub-pixel 12 are arranged in the first direction Y. For example, according to the exemplary embodiment shown in FIG. 18, the third color sub-pixel 13 overlaps with the first color sub-pixel 11 in the second direction X and does not overlap with the second color sub-pixel 12 in the second direction X, and the area of the first color sub-pixel 11 is larger than the area of the second color sub-pixel 12. For example, according to the exemplary embodiment shown in FIG. 19, the third color sub-pixel 13 overlaps with the second color sub-pixel 12 in the second direction X and does not overlap with the first color sub-pixel 11 in the second direction X, and the area of the second color sub-pixel 12 is larger than the area of the first color sub-pixel 11.

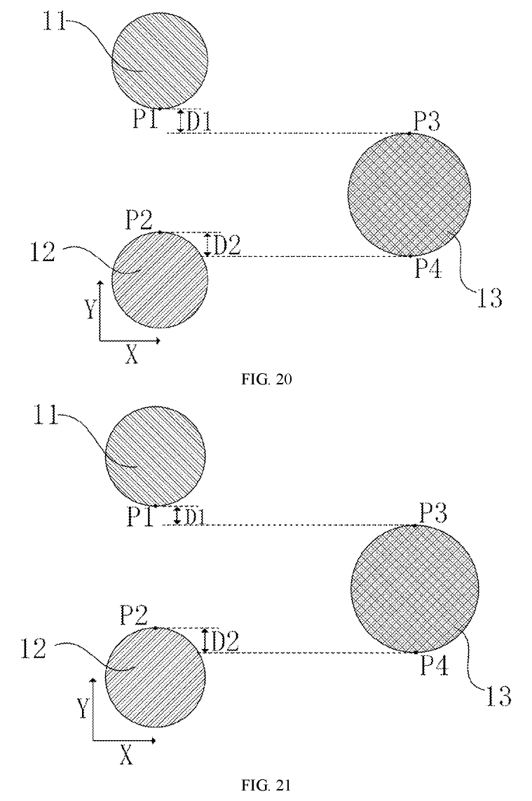

FIG. 20 is a schematic diagram of a pixel unit in a display panel according to an embodiment of the present disclosure.

In the same pixel unit 10, the first color sub-pixel 11 may include a first endpoint P1 close to the second color sub-pixel 12, and the second color sub-pixel 12 may include a second endpoint P2 close to the first color sub-pixel 11, where the first endpoint P1 may be a point in the first color sub-pixel 11 closest to the second color sub-pixel 12 in the same pixel unit 10 in the first direction Y, and the second endpoint P2 may be a point in the second color sub-pixel 12 closest to the first color sub-pixel 11 in the same pixel unit 10 in the first direction Y. In some embodiments, the third color sub-pixel 13 includes a third endpoint P3 and a fourth endpoint P4 opposite to each other along the first direction Y, where the third endpoint P3 and the fourth endpoint P4 are two endpoints in the third color sub-pixel 13 opposite to each other and farthest from each other along the first direction Y. A distance between the third endpoint P3 and the first endpoint P1 in the first direction Y is smaller than a distance between the third endpoint P3 and the second endpoint P2 in the first direction Y, and a distance between the fourth endpoint P4 and the second endpoint P2 in the first direction Y is smaller than a distance between the fourth endpoint P4 and the first endpoint P1 in the first direction Y. According to the exemplary embodiment shown in FIG. 20, the third endpoint P3 is closer to the first color sub-pixel 11 in the first direction Y than the fourth endpoint P4, and the third endpoint P3 is the farthest point in the third color sub-pixel 13 in the first direction Y. The fourth endpoint P4 is closer to the second color sub-pixel 12 in the first direction Y than the third endpoint P3, and the fourth endpoint P4 is the farthest point in the third color sub-pixel 13 in the first direction Y.

In some embodiments, such as the exemplary embodiment shown in FIG. 20, when the third color sub-pixel 13 overlaps with the second color sub-pixel 12 in the second direction X and does not overlap with the first color sub-pixel 11 in the second direction X in the same pixel unit 10, a distance between the third endpoint P3 and the first endpoint P1 in the first direction Y is D1, and a distance between the fourth endpoint P4 and the second endpoint P2 in the first direction Y is D2, where D1 = D2. That is, a width along the first direction Y of the portion of the second color sub-pixel 12 overlapping with the third color sub-pixel 13 in the second direction X is equal to a distance between the first color sub-pixel 11 and the third color sub-pixel 13 in the first direction Y. In this embodiment, the color rendering effect between the second color sub-pixel 12 and the third color sub-pixel 13 can be improved, and the distance between the first color sub-pixel 11 and the second color sub-pixel 12 included in the same pixel unit 10 is not reduced due to the overlapping between the second color sub-pixel 12 and the third color sub-pixel 13 in the second direction X, so as to minimize the diffraction problem caused by a relatively small distance between the sub-pixels.

In some embodiments, when the third color sub-pixel 13 overlaps with the first color sub-pixel 11 in the second direction X and does not overlap with the second color sub-pixel 12 in the second direction X in the same pixel unit 10, a width along the first direction Y of the overlapping portion between the first color sub-pixel 11 and the third color sub-pixel 13 in the second direction X may also be equal to a distance between the second color sub-pixel 12 and the third color sub-pixel 13 in the first direction Y.

In some embodiments, the edge shape of the third color sub-pixel 13 may be a relatively regular circle or ellipse.

FIG. 21 is a schematic diagram of a pixel unit in a display panel according to an embodiment of the present disclosure.

In some embodiments, such as the exemplary embodiment shown in FIG. 21, when the third color sub-pixel 13 overlaps with the second color sub-pixel 12 in the second direction X and does not overlap with the first color sub-pixel 11 in the second direction X in the same pixel unit 10, a distance between the third endpoint P3 and the first endpoint P1 in the first direction Y is D1, and a distance between the fourth endpoint P4 and the second endpoint P2 in the first direction Y is D2, where D1 < D2. That is, a width along the first direction Y of the portion of the second color sub-pixel 12 overlapping with the third color sub-pixel 13 in the second direction X is larger than a distance between the first color sub-pixel 11 and the third color sub-pixel 13 in the first direction Y. In this embodiment, although the first color sub-pixel 11 does not overlap with the third color sub-pixel 13 in the second direction X, the distance between the first color sub-pixel 11 and the third color sub-pixel 13 in the first direction Y is also relatively small, which is conducive to the rendering of the two color sub-pixels, and can avoid an excessively large distance between the first color sub-pixel 11 and the second color sub-pixel 12 in the first direction Y affecting the color rendering between the two.

In addition, when the third color sub-pixel 13 overlaps with the first color sub-pixel 11 in the second direction X and does not overlap with the second color sub-pixel 12 in the second direction X in the same pixel unit 10, a width along the first direction Y of the overlapping portion between the first color sub-pixel 11 and the third color sub-pixel 13 in the second direction X may also be larger than a distance between the second color sub-pixel 12 and the third color sub-pixel 13 in the first direction Y.

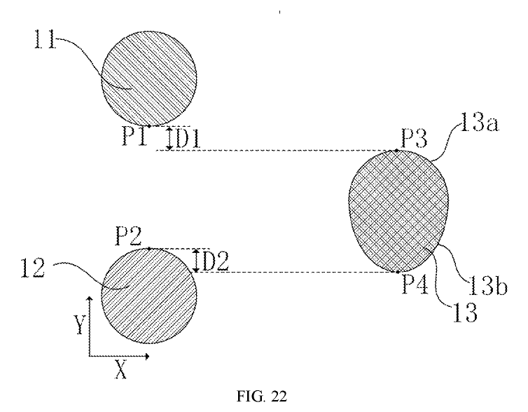

FIG. 22 is a schematic diagram of a pixel unit in a display panel according to an embodiment of the present disclosure.

In some embodiments, such as the exemplary embodiment shown in FIG. 22, when the third color sub-pixel 13 overlaps with the second color sub-pixel 12 in the second direction X and does not overlap with the first color sub-pixel 11 in the second direction X in the same pixel unit 10, the edge shape of the third color sub-pixel 13 includes a circular arc 13a and an elliptical arc 13b that are arranged in the first direction Y, a width of the elliptical arc 13b in the first direction Y is larger than a width of the circular arc 13a in the first direction Y, and the circular arc 13a is located on a side of the elliptical arc 13b away from the fourth endpoint P4 in the first direction Y. That is, the more elongated portion of the third color sub-pixel 13 corresponding to the elliptical arc 13b overlaps with one sub-pixel in the same pixel unit 10 in the second direction X, and the shorter and wider portion of the third color sub-pixel 13 corresponding to the circular arc 13a does not overlap with the sub-pixel in the same pixel unit 10 in the second direction X. In this implementation, the irregularly shaped third color sub-pixel 13 can achieve good rendering effects with both the first color sub-pixel 11 and the second color sub-pixel 12.

In addition, when the third color sub-pixel 13 overlaps with the first color sub-pixel 11 in the second direction X and does not overlap with the second color sub-pixel 12 in the second direction X in the same pixel unit 10, the circular arc 13a in the edge shape of the third color sub-pixel 13 may be located on a side of the elliptical arc 13b away from the third endpoint P3 in the first direction Y.

In some embodiments, such as the exemplary embodiments shown in FIGS. 3, 5, and 7 to 17, an area of the first color sub-pixel 11 is identical to an area of the second color sub-pixel 12.

In some embodiments, with reference to FIGS. 18 and 19, an area of one of the first color sub-pixel 11 and the second color sub-pixel 12 is larger than an area of the other one. For example, according to the exemplary embodiment shown in FIG. 18, the area of the first color sub-pixel 11 is larger than the area of the second color sub-pixel 12. For example, according to the exemplary embodiment shown in FIG. 19, the area of the second color sub-pixel 12 is larger than the area of the first color sub-pixel 11.

In some embodiments, with continued reference to FIGS. 18 and 19, an area of the third color sub-pixel 13 is identical to the area of the one with a larger area of the first color sub-pixel 11 and the second color sub-pixel 12. For example, according to the exemplary embodiment shown in FIG. 18, the area of the first color sub-pixel 11 is larger than the area of the second color sub-pixel 12, and the area of the first color sub-pixel 11 is identical to the area of the third color sub-pixel 13; For example, according to the exemplary embodiment shown in FIG. 19, the area of the second color sub-pixel 12 is larger than the area of the first color sub-pixel 11, and the area of the second color sub-pixel 12 is identical to the area of the third color sub-pixel 13.

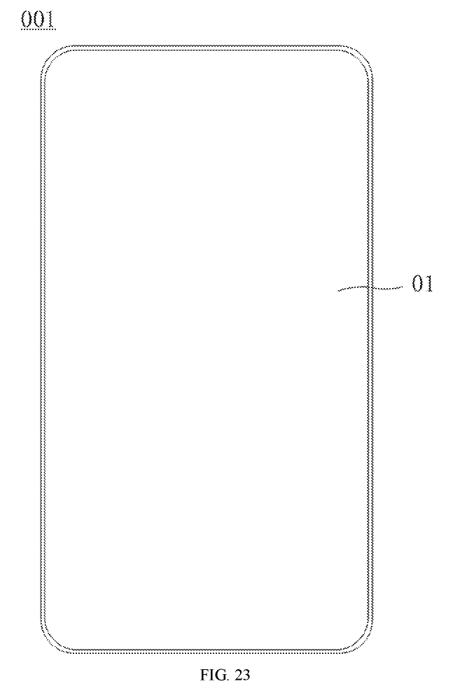

FIG. 23 is a schematic diagram of a display apparatus according to an embodiment of the present disclosure.

According to the exemplary embodiment shown in FIG. 23, an embodiment of the present disclosure further provides a display apparatus 001, including the display panel 01 according to any of the foregoing embodiments. Of course, it should be understood that the display apparatus 001 as shown in FIG. 23 is merely illustrative, and the display apparatus 001 may be any electronic device having a display function, such as a mobile phone, a tablet computer, a notebook computer, an e-book, a television, and a splicing display apparatus.

The above are merely preferred embodiments of the present disclosure and are not intended to limit the present disclosure. It should be noted that any modifications, equivalent substitutions, improvements, and the like made within the spirit and principle of the present disclosure shall fall within the scope of the present disclosure.

What is claimed is:

1. A display panel, comprising a plurality of pixel units, wherein a pixel unit of the plurality of pixel units comprises a first color sub-pixel, a second color sub-pixel, and a third color sub-pixel, and edge shapes of the first color sub-pixel, the second color sub-pixel, and the third color sub-pixel are all non-linear shapes; and
wherein in a same pixel unit, the first color sub-pixel and the second color sub-pixel are arranged along a first direction, the third color sub-pixel and a region between the first color sub-pixel and the second color sub-pixel are arranged along a second direction, and the third color sub-pixel does not overlap with at least one of the first color sub-pixel and the second color sub-pixel in the second direction.

2. The display panel according to claim 1,
wherein the edge shape of the first color sub-pixel comprises at least one of a circular arc and an elliptical arc;
wherein the edge shape of the second color sub-pixel comprises at least one of a circular arc and an elliptical arc; and
wherein the edge shape of the third color sub-pixel comprises at least one of a circular arc and an elliptical arc.

3. The display panel according to claim 2, wherein the edge shape of the third color sub-pixel is a circle.

4. The display panel according to claim 2, wherein the edge shape of the third color sub-pixel is an ellipse, and a major axis of the ellipse is parallel to the first direction.

5. The display panel according to claim 2, wherein the edge shape of the third color sub-pixel comprises the circular arc and the elliptical arc arranged along the first direction, and a major axis of an ellipse corresponding to the elliptical arc is parallel to the first direction.

6. The display panel according to claim 3, wherein the edge shape of at least one of the first color sub-pixel and the second color sub-pixel is a circle.

7. The display panel according to claim 3,
wherein the edge shape of at least one of the first color sub-pixel and the second color sub-pixel is an ellipse; and
wherein a major axis of the ellipse is parallel to the second direction.

8. The display panel according to claim 3,
wherein the edge shape of at least one of the first color sub-pixel and the second color sub-pixel comprises the circular arc and the elliptical arc arranged along the second direction; and
wherein a major axis of ellipse corresponding to the elliptical arc is parallel to the second direction.

9. The display panel according to claim 1, wherein in the same pixel unit, the third color sub-pixel does not overlap with the first color sub-pixel and the second color sub-pixel in the second direction.

10. The display panel according to claim 9, wherein a first center line of the edge shape of the third color sub-pixel is parallel to the second direction; and
in the same pixel unit, a distance between the first center line of the third color sub-pixel and the first color sub-pixel in the first direction is d1, a distance between the first center line of the third color sub-pixel and the second color sub-pixel in the first direction is d2, and d1 = d2.

11. The display panel according to claim 9, wherein in the same pixel unit, a distance between the third color sub-pixel and the first color sub-pixel in the first direction is D1, a distance between the third color sub-pixel and the second color sub-pixel in the first direction is D2, and D1 = D2.

12. The display panel according to claim 9, wherein in the same pixel unit, a distance between the third color sub-pixel and the first color sub-pixel in the first direction is D1, a distance between the third color sub-pixel and the second color sub-pixel in the first direction is D2, and D1 < D2 or D1 > D2.

13. The display panel according to claim 1, wherein in the same pixel unit, the third color sub-pixel partially overlaps with the first color sub-pixel in the second direction and does not overlap with the second color sub-pixel in the second direction.

14. The display panel according to claim 13, wherein in the same pixel unit, the first color sub-pixel comprises a first endpoint close to the second color sub-pixel, the second color sub-pixel comprises a second endpoint close to the first color sub-pixel, and the third color sub-pixel comprises a third endpoint and a fourth endpoint opposite to each other along the first direction; and
in the same pixel unit, a distance between the third endpoint and the first endpoint in the first direction is smaller than a distance between the third endpoint and the second endpoint in the first direction, a distance between the fourth endpoint and the second endpoint in the first direction is smaller than a distance between the fourth endpoint and the first endpoint in the first direction, a distance between the third endpoint and the first endpoint in the first direction is D1, a distance between the fourth endpoint and the second endpoint in the first direction is D2, and D1 = D2.

15. The display panel according to claim 14, wherein the edge shape of the third color sub-pixel is a circle or an ellipse.

16. The display panel according to claim 13, wherein in the same pixel unit, the first color sub-pixel comprises a first endpoint close to the second color sub-pixel, the second color sub-pixel comprises a second endpoint close to the first color sub-pixel, and the third color sub-pixel comprises a third endpoint and a fourth endpoint opposite to each other along the second direction; and
in the same pixel unit, a distance between the third endpoint and the first endpoint in the first direction is smaller than a distance between the third endpoint and the second endpoint in the first direction, a distance between the fourth endpoint and the second endpoint in the first direction is smaller than a distance between the fourth endpoint and the first endpoint in the first direction, a distance between the third endpoint and the first endpoint in the first direction is D1, a distance between the fourth endpoint and the second endpoint in the first direction is D2, and D1 < D2.

17. The display panel according to claim 16, wherein the edge shape of the third color sub-pixel comprises the circular arc and the elliptical arc arranged along the first direction, and the elliptical arc is located on a side of the circular arc away from the fourth endpoint in the first direction; and a width of the elliptical arc in the first direction is larger than a width of the circular arc in the first direction.

18. The display panel according to claim 1, further comprising:
a light-emitting material layer comprising a first color light-emitting material block, a second color light-emitting material block, and a third color light-emitting material block, wherein edge shapes of the first color light-emitting material block, the second color light-emitting material block, and the third color light-emitting material block are all rectangular; and
a pixel defining layer comprising a first opening, a second opening, and a third opening, wherein an edge shape of the first opening, an edge shape of the second opening, and an edge shape of the third opening are non-linear shapes; the first color sub-pixel comprises a portion of the first color light-emitting material block located in the first opening, the second color sub-pixel comprises a portion of the second color light-emitting material block located in the second opening, and the third color sub-pixel comprises a portion of the third color light-emitting material block located in the third opening.

19. The display panel according to claim 18, wherein a second center line of the edge shape of the third color light-emitting material block is parallel to the second direction; and
in the first color light-emitting material block, the second color light-emitting material block, and the third color light-emitting material block respectively corresponding to the first color sub-pixel, the second color sub-pixel, and the third color sub-pixel in the same pixel unit, the second center line of the third color light-emitting material block coincides with a boundary line between the first color light-emitting material block and the second color light-emitting material block.

20. A display apparatus, comprising a display panel, wherein the display panel comprises a plurality of pixel units, a pixel unit of the plurality of pixel units comprises a first color sub-pixel, a second color sub-pixel, and a third color sub-pixel, and edge shapes of the first color sub-pixel, the second color sub-pixel, and the third color sub-pixel are all non-linear shapes; and
wherein in a same pixel unit, the first color sub-pixel and the second color sub-pixel are arranged along a first direction, the third color sub-pixel and a region between the first color sub-pixel and the second color sub-pixel are arranged along a second direction, and the third color sub-pixel does not overlap with at least one of the first color sub-pixel and the second color sub-pixel in the second direction.
